(19) United States
(12) Patent Application Publication
(10) Pub. No.: US 2024/0429827 A1
(43) Pub. Date: Dec. 26, 2024

(54) Flyback Switch Converter and Control Circuit Thereof

(71) Applicant: Joulwatt Technology Co., Ltd., Hangzhou (CN)

(72) Inventors: Xiangyong XU, Hangzhou (CN); Xianghua JIANG, Hangzhou (CN)

(21) Appl. No.: 18/748,516

(22) Filed: Jun. 20, 2024

(30) Foreign Application Priority Data
Jun. 21, 2023 (CN) 202310748128.5

(51) Int. Cl. H02M 3/335; H02M 1/32; H02M 3/00

(52) U.S. Cl. CPC H02M 3/33571; H02M 1/32; H02M 3/01

(57) ABSTRACT

The present application relates to a flyback switch converter and a control circuit thereof; the control circuit comprises: a control signal generation module for providing a first control signal; a driver, for supplying a first switch transistor with a first driving signal according to the first control signal, so as to control the turning-on and off of the first switch transistor; the driver is further for performing overcurrent detection according to the voltage drop across the first switch transistor when the flyback switch converter performs the power output, and supplying a resonant capacitor with a discharge path when the flyback switch converter is shut down or enters the protection state. The present application can discharge residual charges on the resonant capacitor when the system is shut down or enters the protection state, and the system is less complex and with lower cost.

### CROSS-REFERENCE TO RELATED APPLICATION

This application claims priority to Chinese patent application No. 202310748128.5, filed on Jun. 21, 2023, and entitled “FLYBACK SWITCH CONVERTER AND CONTROL CIRCUIT THEREOF”, the entire contents of which are incorporated by reference.

### FIELD

The present application relates to the technical field of switch power supply, more particularly, to a flyback switch converter and a control circuit thereof.

### BACKGROUND

With the rapid development of the power electronics field, the application of switch converters is becoming more and more widespread; especially, more requirements are made for high power density, high reliability, and small volume switch converters. Traditional low-power switch converters are generally implemented by using flyback topology, which has the advantages of simple structure and low cost. Wherein, asymmetric half-bridge (AHB) converter has the additional advantage of isolation, and can realize zero voltage conduction of two switching transistors, recover leakage inductance energy, and easily achieve self-driving synchronous rectification under conditions that the number and complexity are similar to that of the conventional PWM or quasi-resonant flyback converters. It effectively improves efficiency while reducing the volume of the transformer, making it a good application solution.

However, after the traditional AHB is shut down, there are residual charges in the resonant capacitor, and the residual charges will generate large current in part of the devices on the circuit when the AHB is powered on again, which affects device reliability.

Therefore, it is necessary to provide an improved technical solution to overcome the above technical problems in the prior art.

### SUMMARY

In order to solve the above technical problem, the present application provides a flyback switch converter and a control circuit thereof, which can resolve the residual charge release problem on the resonant capacitor when the system is shut down, and can reduce system complexity and cost.

According to the first aspect of the present application, a control circuit of a flyback switch converter is provided, and the flyback switch converter comprises: a transformer, a first switch transistor, and a resonant capacitor in a resonant circuit formed when the first switch transistor is in turn-on state, and the control circuit is coupled to the first switch transistor, wherein the control circuit comprises:
a driver, coupled to the control signal generation module and the first switch transistor, to supply the first switch transistor with a first driving signal according to the first control signal, so as to control the first switch transistor to be turned on and off,
wherein the driver is for performing overcurrent detection according to a voltage drop across the first switch transistor when the flyback switch converter performs power output, and supplying the resonant capacitor with a discharge path when the flyback switch converter is shut down or enters a protection state.

Optionally, the driver receives an enabling signal, and works in an overcurrent detection modes when the enabling signal is valid and works in a discharge mode when the enabling signal is invalid,
wherein the enabling signal is invalid when the flyback switch converter is shut down or enters the protection state, otherwise the enabling signal is valid;
in the overcurrent detection mode, the driver performs the overcurrent detection when the first driving signal is valid;
in the discharge mode, the driver supplies the resonant capacitor with the discharge path.

Optionally, the driver comprises a second switch transistor;
in the overcurrent detection mode, the second switch transistor is controlled by the first driving signal to operate in turn-on or turn-off state, and the driver is configured to sample the voltage drop across the first switch transistor when the second switch transistor is in turn-on state to perform the overcurrent detection;
in the discharge mode, the second switch transistor is controlled by the enabling signal to turn on for at least the first time, and the driver is configured to supply the resonant capacitor with the discharge path when the second switch transistor is in turn-on state.

Optionally, the discharge path comprises:
an energy consumption element, having a first terminal coupled to a reference ground, and a second terminal coupled to the resonant capacitor via the second switch element.

Optionally, the driver comprises a second switch transistor and a third switch transistor;
in the overcurrent detection mode, the second switch transistor is controlled by the first driving signal to operate in turn-on or turn-off state, and the third switch transistor is controlled by the enabling signal to operate in turn-off state, the driver is configured to sample the voltage drop across the first switch transistor when the second switch transistor is in turn-on state to perform the overcurrent detection;
in the discharge mode, the second switch transistor and the third switch transistor are controlled by the enabling signal to turn on for at least the first time, and the driver is configured to supply the resonant capacitor with the discharge path when the second switch transistor and the third switch transistor are in turn-on state.

Optionally, the discharge path comprises:
an energy consumption element, having a first terminal coupled to a reference ground via the third switch transistor, and a second terminal coupled to the resonant capacitor via the second switch transistor.

Optionally, the energy consumption element comprises a resistor element.

Optionally, in the overcurrent detection mode, the second switch transistor is controlled by the first driving signal to turn on when the first switch transistor is turned on, so that the driver can sample the voltage drop across the first switch transistor when the first switch transistor is turned on to obtain the sampling signal,
wherein the driver outputs a valid overcurrent protection signal when the sampling signal is greater than a preset overcurrent protection threshold, and controls the flyback switch converter to operate in the overcurrent protection state.

Optionally, the driver further comprises:
a comparison circuit, having a first input terminal coupled to the second switch transistor to receive the sample signal when the second switch transistor is turned on, a second input terminal that receives an overcurrent protection threshold, and an output terminal that outputs the overcurrent protection signal.

Optionally, the driver further comprises:
an AND gate logic circuit, having a first input terminal that receives the overcurrent protection signal, a second input terminal that receives the first control signal, and an output terminal that outputs the first driving signal.

Optionally, the driver further comprises:
a discharge control unit, having an input terminal that receives the enabling signal, and an output terminal that outputs the discharge control signal; wherein the discharge control unit is configured to control a conducting time of the second switch transistor in the discharge mode;
an OR gate logic circuit, having a first input terminal that receives the first driving signal, a second input terminal that receives the discharge control signal, and an output terminal coupled to a control end of the second switch transistor.

Optionally, the discharge control unit is configured to continuously output the discharge control signal at valid state when the received enabling signal is in invalid state.

Optionally, the discharge control unit is configured to output the discharge control signal at valid state within the first time after the received enabling signal is changed to invalid state.

Optionally, the discharge control unit comprises:

NOT gate logic circuit, having an input terminal that receives the enabling signal, and an output terminal that outputs the discharge control signal.

Optionally, the discharge control unit comprises:
a timer, which receives the enabling signal and starts timing when the enabling signal is changed to invalid state, and stops timing when an obtained timing value reaches a timing threshold, which represents the first time,
wherein the timer is configured to output the discharge control signal at valid state during the timing.

Optionally, the timing threshold is a preset value.

Optionally, the timing threshold is determined in response to a detection result of a voltage across two ends of the resonant capacitor.

Optionally, the discharge control unit further comprises:
a voltage detection unit for detecting the voltage across the two ends of the resonant capacitor in the discharge mode, and generating a triggering signal when the voltage across the two ends of the resonant capacitor drops to a preset voltage threshold, to trigger the timer to stop timing.

According to a second aspect of the present application, a flyback switch converter is provided, and comprises:
a transformer, a main switch transistor, a first switch transistor, and a resonant capacitor formed in the resonant circuit when the first switch transistor is in turn-on state;
the control circuit of any one of the embodiments of the present application, coupled to the main switch transistor and the first switch transistor, respectively, to control the main switch transistor and the first switch transistor to be turned on and off, wherein the control circuit is further for performing overcurrent detection when the flyback switch transformer performs the power output according to the voltage drop across the first switch transistor, and supplying the resonant capacitor with the discharge path when the flyback switch converter is shut down or enters the protection state.

Optionally, the main switch transistor and the first switch transistor are sequentially connected in series between an input terminal of the flyback switch converter and a reference ground.

Optionally, the first switch transistor and the main switch transistor are sequentially connected between the input terminal of the flyback switch converter and the reference ground.

Optionally, the resonant capacitor, the first switch transistor, and the main switch transistor are sequentially connected in series between the input terminal of the flyback switch converter and the reference ground.

The present application at least has the following advantageous effects:

Embodiments of the present application set that the driver in the switch converter system can release the residual charges on the resonant capacitor when the system is shut down or enters the protection state while making overcurrent protection on the system, which is equivalent to integrating the overcurrent detection line and at least part of the discharge path simultaneously in the driver; moreover, since the overcurrent detection function for the driver and the discharge function for the resonant capacitor occur at different time periods, the overcurrent detection line and the discharge path can be used repeatedly, which not only improves the integration, but also reduces system complexity and cost.

It should be noted that the above general description and the later detailed descriptions are merely exemplary and interpretive, rather than restricting the present application.

### BRIEF DESCRIPTION OF THE DRAWINGS

FIG. 1A shows a circuit diagram of a flyback switch converter of an asymmetric half-bridge topology form;

FIG. 1B shows a circuit diagram of a flyback switch converter of another asymmetric half-bridge topology form;

FIG. 1C shows a circuit diagram of a flyback switch converter of an active clamp topology form;

FIG. 2 shows a circuit diagram of a flyback switch converter;

FIG. 3 shows a circuit diagram of a flyback switch converter provided according to the embodiments of the present application;

FIG. 4 shows a circuit diagram of the driver in FIG. 3 provided according to the first embodiment of the present application;

FIG. 5 shows a circuit diagram of the driver in FIG. 3 provided according to the second embodiment of the present application;

FIG. 6 shows a circuit diagram of the driver in FIG. 3 provided according to the third embodiment of the present application;

FIG. 7 shows a circuit diagram of the driver in FIG. 3 provided according to the fourth embodiment of the present application.

### DETAILED DESCRIPTION

In order to understand the present application, the following will make comprehensive description on the present application by referring to the related accompanying drawings. The accompanying drawings give the preferred embodiments of the present application. However, the present application may be implemented by different forms, not restricted by the embodiments described in this text. On the contrary, the objective of providing these embodiments is to make the understanding of the disclosure of the present application more thorough and compensative.

For the description in the specification like, “an embodiment” or “some embodiments”, they mean that one or more embodiments of the present application include specific features, structures or features described by combining with the embodiments. Thus, for phrases appearing in different parts of the specification, “in an embodiment”, “in some embodiments”, “in some other embodiments”, “in some additional embodiments”, they do not necessarily refer to the same embodiments, but mean “one or more but not all embodiments”, otherwise specifically emphasized in other forms. Terms like “include”, “comprise”, “have” and their deformations all mean “include but not limited to”, unless specifically emphasized in other forms.

In the description of the present application, works like “schematically” or “for example” are used as an example, an example illustration, or explanation. Any embodiments in the present application described as “exemplary” or “for example” should not be interpreted as more preferred or more advantageous than other embodiments. The expression “and/or” in this text is a description for the related relationship of associated objects, and it can denote three relationships, e.g., A and/or B may denote three conditions of only A, A and B meanwhile, and only B. The word “more” refers to two or more than two. In addition, in order to clearly describe the technical solutions in the embodiments of the present application, words like “first”, “second” are used to distinguish the same or similar items of the substantially the same functions. Those skilled in the art may understand that the words like “first”, “second” do not restrict the number or the execution sequences, and the words like “first”, “second” do not restrict that they are not different definitely.

In addition, the same reference signs in the figures denote the same or similar structures, and thus repeated descriptions will be omitted, i.e., the respective parts in this description will be described in parallel and progressively, and each part emphases differences with other parts, and for the same or similar parts, mutual reference can be made.

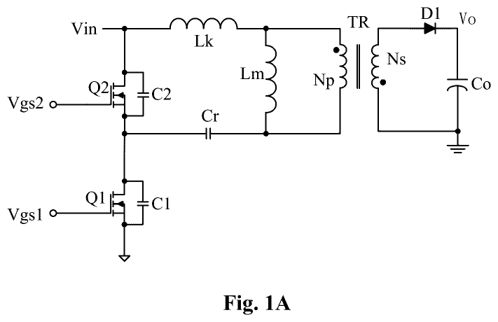

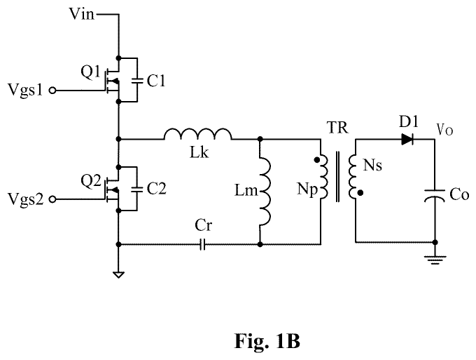

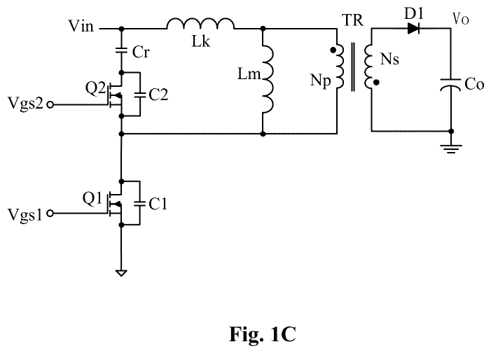

FIG. 1A shows a schematic view of an asymmetric half-bridge topology of the flyback switch converter. For clarity, the drawing merely shows the main circuit of the flyback switch converter, but does not show the control circuit for supplying the switch transistor with a switch control signal.

In the asymmetrical half-bridge topology shown in FIG. 1A, the flyback switch converter comprises: a transformer TR with a primary edge winding Np and a secondary edge winding Ns, switch transistors Q1 and Q2 located at the primary edge of the transformer TR, inductor Lk and the resonant capacitor Cr, and diode D1 and output capacitor Co located at the secondary edge of the transformer TR.

At the primary edge of the transformer TR, switch transistors Q1 and Q2 are sequentially connected in series between the input terminal of the voltage and the reference ground of the primary edge. In a possible embodiment, switch transistors Q1 and Q2 are both NMOS field-effect transistor. The primary edge winding Np, the inductor Lk of the transformer TR and the resonant capacitor Cr are connected in series between the source and drain of the switch transistor Q2, and form a resonant circuit when the switch transistor Q2 is turned on. The primary edge winding of the transformer TR is an excitation inductance in the equivalent inductor of the resonant circuit.

At the secondary edge of the transformer TR, diode D1 and the secondary edge winding Ns of the transformer TR are connected in series between the voltage output end of the reference ground of the secondary edge. The anode of diode D1 is connected to the heteronymous end of the secondary edge winding Ns, so as to rectify the inductance voltage which is in opposite phase with the excitation inductance of the transformer TR so as to provide a direct current output voltage Vo. The output voltage Co is connected between the voltage output terminal and the reference ground of the secondary edge, and the direct current output voltage Vo is filtered to obtain a smooth voltage waveform. In an alternative embodiment, it may use a synchronous rectifying switch transistor to replace diode D1.

Preferably, the flyback switch converter further comprises a sampling resistor connected between the source of the switch transistor Q2 and the reference ground, for, during the period when switch transistor Q1 is turned on and switch transistor Q2 is turned off, obtaining the current flowing through transistor Q1. Optionally, in low-power power supply applications, the leakage inductance of transformer TR can be used to replace the inductance Lk.

FIG. 1B shows a schematic view of another asymmetric half-bridge topology of the flyback switch converter. For clarity, the figure merely shows the main circuit of the flyback switch converter, and does not show the control circuit for supplying the switch transistor with the switch control signal.

In the asymmetric half-bridge topology shown in FIG. 1B, the flyback switch converter comprises: a transformer TR with a primary edge winding Np and a secondary edge winding NS, switch transistors Q1 and Q2, inductor Lk, and resonant capacitor Cr located at the primary edge side of the transformer TR, diode D1 and the output capacitor Co located at the secondary edge side of the transformer TR.

At the primary edge side of the transformer TR, switch transistors Q2 and Q1 are sequentially connected in series between the voltage input terminal and the reference ground of the primary edge. In a possible embodiment, switch transistors Q1 and Q2 are both NMOS field-effect transistors. The primary edge winding Np, inductor Lk, and resonant capacitor Cr of the transformer TR are connected in series between the source and drain of the switch transistor Q2, and form a resonant circuit when switch transistor Q2 is turned on. The equivalent inductor of the primary edge winding of transformer Tr in the resonant circuit is an excitation inductance.

At the secondary edge side of the transformer TR, diode D1 and the secondary edge winding Ns of the transformer TR are connected in series between the voltage output end and the reference ground of the secondary edge. The anode of diode D1 is connected to the heteronymous end of the secondary edge winding NS, so as to rectify the induced voltage of which the phase is opposite to that of the excitation inductance to provide a direct current output voltage Vo. The output capacitor Co is connected between the voltage output end and the reference ground of the secondary edge, filters the direct current output voltage Vo to obtain smooth voltage waveforms. In an alternative embodiment, it may use the synchronous rectifying switch transistors to replace diode D1.

Preferably, the flyback switch converter further comprises a sampling resistor connected between the source of switch transistor Q2 and the reference ground, for obtaining the current flowing through switch transistor Q1 when switch transistor Q1 is turned on and switch transistor Q2 is turned off. Preferably, in low-power power supply applications, the leakage inductance of transformer TR can be used to replace the inductor Lk.

FIG. 1C shows a schematic view of an active clamp topology of the flyback switch converter. For clarity, the figure merely illustrates the main circuit of the flyback switch converter, but does not show the control circuit for supplying the switch transistor with switch control signals.

In the active clamp topology shown in FIG. 1C, the flyback switch converter comprises: transformer TR with a primary edge winding Np and a secondary edge winding Ns, switch transistors Q1 and Q2, inductor Lk, and capacitor Cr located at the primary edge side of transformer TR, diode D1 and output capacitor Co located at the secondary edge side of transformer TR.

At the secondary edge of transformer TR, inductor Lk, the primary edge winding NP of transformer TR and switch transistor Q1 are sequentially connected in series between the voltage input end and the reference ground of the primary edge, and capacitor Cr and switch transistor Q2 are sequentially connected in series between the voltage input terminal and switch transistor Q1; in other words, capacitor Cr, switch transistor Q2, and switch transistor Q1 are sequentially connected in series between the voltage input terminal and the reference ground of the primary edge. In a possible embodiment, switch transistors Q1 and Q2 are both NMOS field-effect transistor. Capacitor Cr and switch transistor Q2 form an active clamp circuit. When switch transistor Q1 is turned off and switch transistor Q2 is turned on, the primary edge winding NP of transformer TR, inductor Lk, and capacitor Cr form a resonant circuit. The equivalent inductor Lm of the primary edge winding of transformer TR in the resonant circuit is an excitation inductor Lm.

In the flyback switch converter of the active clamp topology, capacitor Cr is not only used as the clamp capacitor, but also used as the resonant capacitor in the resonant circuit. Capacitor Cr can absorb the leakage energy, and thus inhibiting the peak voltage of the converter and improving circuit efficiency. Meanwhile, the working principle of capacitor Cr used as the resonant capacitor is similar to that of the flyback switch converter of the asymmetrical half-bridge topology.

At the secondary edge of transformer TR, diode D1 and the secondary edge winding Ns of transformer TR are connected in series between the voltage output terminal and the reference ground of the secondary edge. The anode of diode D1 is connected to the heteronymous end of the secondary edge winding Ns, so as to rectify the induced voltage in the opposite phase to the excitation voltage of the transformer TR to provide direct current output voltage Vo. The output voltage Co is connected between the voltage output end and the reference ground of the secondary edge, and filters direct current output voltage Vo to obtain smooth voltage waveforms.

Preferably, the flyback switch converter further comprises a sampling resistor connected between the source of switch transistor Q2 and the reference ground, which is for obtaining the current flowing through the switch transistor Q1 when the switch transistor Q1 is turned on and switch transistor Q2 is turned off. Preferably, in low-power power supply applications, the leakage inductance of transformer TR can be used to replace the inductor Lk.

In the application scenarios of the flyback switch converter (also called converter, converter system or system for short in this text), e.g., in the conditions of input voltage power failure, abnormal occurrence, insufficient power supply, the converter may stop working. According to the existing flyback switch converter, the capacitor Cr is stored with charges before stop working (e.g., shut down or entering into the protection state); after stopping work, since the discharge of capacitor Cr is very flow, after it is restarted, when switch transistor Q2 is driven to turn on, since there are residual charges in capacitor Cr, capacitor Cr will rapidly charge the output capacitor Co at the secondary edge side through transformer TR, thus generating grate current on switch transistor Q2 and/or diode D1, which may easily reduce the reliability of the device and the converter system.

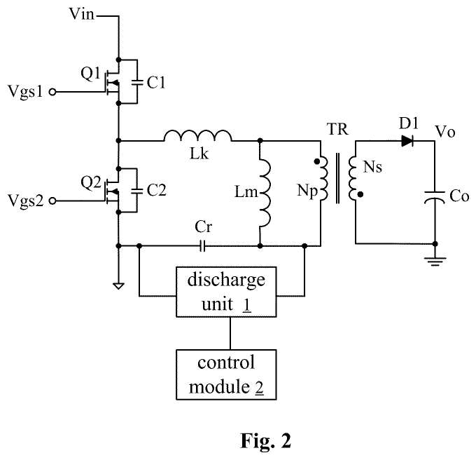

For the above problem, take the flyback switch converter of the asymmetric half-bridge topology form shown in FIG. 1B as an example, FIG. 2 shows a further optimized solution. In the example shown in FIG. 2, the two ends of the resonant capacitor Cr are additional connected in series with a discharge unit 1, and the discharge control unit is controlled by the control module 2, which can supply the resonant capacitor Cr with a discharge path when it is shut down or enters the protection state. However, the solution needs to additionally add new discharge lines and control lines, which increase system cost and complexity.

For this problem, also take the flyback switch coveter of the asymmetric half-bridge topology form shown in FIG. 1B as an example, the embodiments of the present application provides another optimized solution, and by using the relationship that the discharge process of the resonant capacitor and the overcurrent detection process for the system occur in different time periods, by integrating the resonant capacitor discharge function in the driver with an overcurrent detection function of the corresponding switch transistor Q2, the driver may use part of the overcurrent detection line during the non-overcurrent detection time period to realize the discharge of the resonant capacitor, and further by using the overcurrent detection line of the complex driver, it not only improves system integration, but also reduces complexity and cost.

It can be understood that the optimized solution provided by the embodiments of the present application also applies in various flyback switch converters which perform resonant processes by using capacitor during other power output process of the asymmetric half-bridge topology shown in FIG. 1A and the active clamp topology shown in FIG. 1C, and the thus obtained technical solutions also belong to the protection contents of the present application.

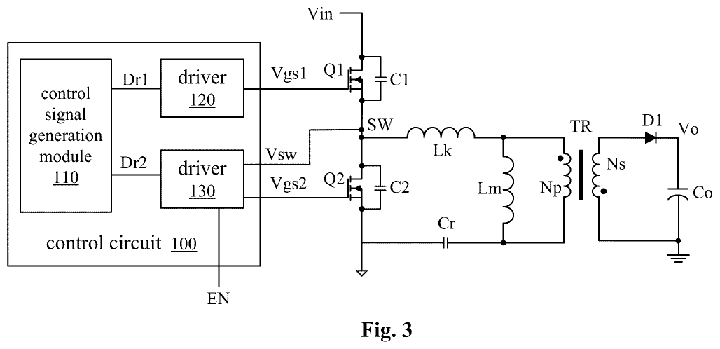

FIG. 3 shows a circuit schematic view of the flyback switch converter provided by the embodiments of the present application. In the example shown in FIG. 3, the flyback switch converter comprises: the main circuit part of the flyback switch converter and the control circuit 100 coupled to the main circuit part; wherein, the main circuit part of the flyback switch converter comprises a transformer TR, switch transistor Q1, switch transistor Q2, resonant capacitor Cr, inductor Lk, diode D1, and output capacitor Co. It can be understood that the main circuit part has the same structure as that in FIG. 1B; for specific details, please refer to the above description of FIG. 1B, which will not be repeated here.

The control circuit 100 is coupled to switch transistors Q1 and Q2 respectively; on one hand, the control circuit 100 is for supplying switch transistors Q1 and Q2 with driving signals Vgs1 and Vgs2, to control the switch transistors Q1 and Q2 to turn on and off; on the other hand, the control circuit 100 is further performing the overcurrent detection according to the voltage drop across the switch transistor Q2 when the flyback switch converter performs power output, and supplies the resonant capacitor Cr with a discharge circuit when the flyback switch converter is shut down or enters the protection state.

In this embodiment, the control circuit 100 comprises: a control signal generation module 110, a driver 120, and a driver 130.

Wherein the control signal generation module 110 is for providing the control signals Dr1 and Dr2 of switch transistor Q1 and switch transistor Q2 respectively.

Under the control of control signals Dr1 and Dr2, switch transistors Q1 and Q2 are turned on and off in a complimentary way, e.g., according to a predetermined switch cycle. When switch transistor Q1 is turned on and switch transistor Q2 is turned off, the resonant capacitor Cr is charged to make the voltage (marked as Vcr) across the two ends of the resonant capacitor Cr raise. When switch transistor Q1 is turned off and switch transistor Q2 is turned on, the resonant circuit works, and the resonant capacitor Cr discharges by way of providing resonant current to transfer the electric energy from the primary edge side of the transformer to the secondary edge side. The regulation of the direct current output voltage Vo is realized by regulating the duty cycle of the control signal. In an alternative embodiment, switch transistors Q1 and Q2 can be turned on and off in a non-complementary way according to a predetermined switch cycle, e.g., setting a dead time. Wherein, for the structures and realization principles of the control circuit 110, they can be understood by referring to the prior art, and are not described in details here.

Driver 120 is coupled to the control signal generation circuit 110 and switch transistor Q1 respectively, receives the control signal Dr1, and outputs the driving signal Vgs1 according to the control signal Dr1 to regulate the gate voltage of the switch transistor Q1, to control the switch transistor Q1 to be turned on and off.

Driver 130 is coupled to the control signal generation circuit 110 and the switch transistor Q2 respectively, receives the control signal Dr2, and regulates the gate voltage of the switch transistor Q2 according to the driving signal Vgs2 output by the control signal Dr2, to control the switch transistor Q2 to be turned on and off.

In this embodiment, driver 130 is further for performing overcurrent detection according to the voltage drop across the switch transistor Q2 when the flyback switch converter makes the power output, and supplying the resonant capacitor Cr with a discharge path when the flyback switch converter is shut down or enters the protection state.

The work state of the flyback switch converter is, e.g., indicated by the enabling signal EN, wherein the enabling signal EN is the invalid state when the flyback switch converter is shut down or enters the protection state, otherwise the enabling signal EN is in the valid state (e.g., the enabling signal EN is in the valid state when the flyback switch converter performs the power output). In this embodiment, the valid state of the enabling signal EN is high-level sate, and in the invalid state, it is the low-level state; however, other embodiments are also possible, e.g., it may be that the valid state of the enabling signal EN is the low level state, and the invalid state is the high level state.

During specific implementation, driver 130 receives the enable signal EN and operates in the overcurrent detection mode when the enable signal EN is valid, and operates in the discharge mode when the enable signal EN is invalid. Wherein in the overcurrent detection mode, driver 130 performs the overcurrent detection when the driving signal Vgs1 is valid; while in the discharge mode, driver 130 supplies the resonant capacitor with a discharge path.

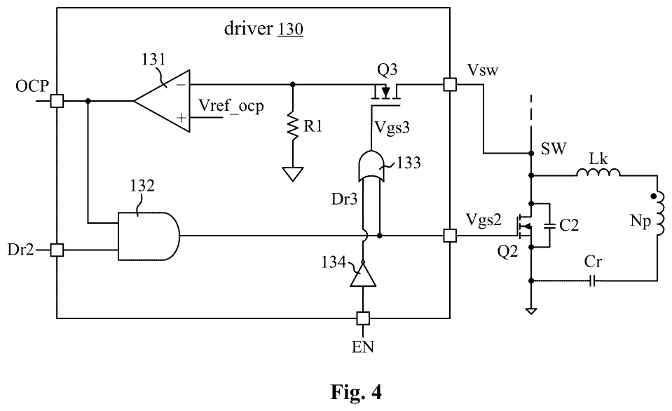

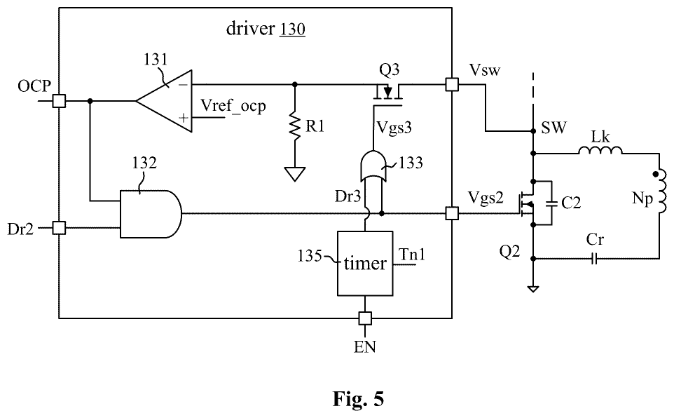

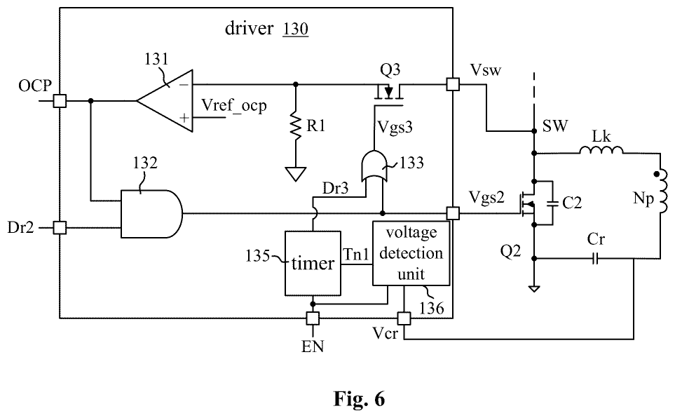

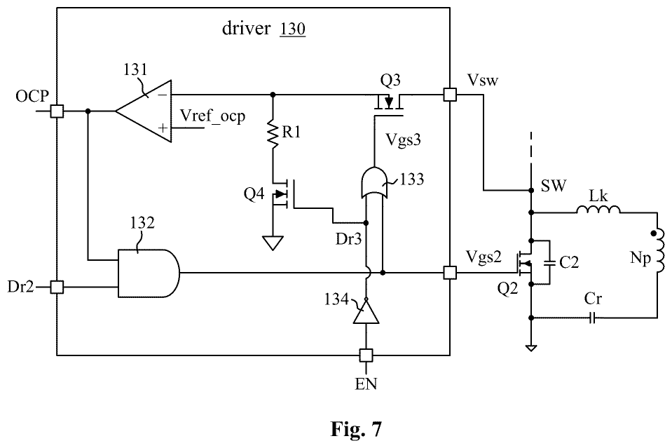

It can be known based on the principle of overcurrent detection that during overcurrent detection, driver 130 needs to sample the voltage drop across switch transistor Q2 during the period when switch transistor Q1 is turned off and switch transistor Q2 is turned on (for example, it can be obtained by sampling voltage V_{SW} of node SW), and determines whether the current flowing through switch transistor Q2 is overcurrent when switch transistor Q2 is turned on by voltage V_{SW}, so as to determine whether the converter system is overcurrent. Based on this, the internal circuit schematic diagram of driver 130 in the embodiments of the present application can be shown in as any one of FIG. 4, FIG. 5, FIG. 6, and FIG. 7.

In the example shown in FIG. 4, driver 130 comprises: switch transistor Q3, comparator 131, AND gate logic circuit 132, OR gate logic circuit 133, NOT gate logic circuit 134, and resistor R1. Wherein the source of switch transistor Q3 is coupled to the negative phase input terminal of comparator 131; the drain is coupled to node SW, and the gate receives driving signal Vgs3; the positive phase input terminal of comparator 131 receives a preset overcurrent protection threshold Vref_ocp, and the output terminal outputs an overcurrent protection signal OCP; the first terminal of resistor R1 is coupled to the reference ground, and the second terminal is coupled to the source of switch transistor Q3, and then coupled to the resonant capacitor Cr through switch transistor Q3; the first input terminal of AND gate logic circuit 132 is coupled to the output terminal of comparator 131 to receive the overcurrent protection signal OCP; the second input terminal of AND gate logic circuit 132 receives a control signal Dr2, and the output terminal of AND gate logic circuit 132 outputs a driving signal Vgs2; the input end of the NOT gate logic circuit 134 receives an enabling signal EN, and the output end of the NOT gate logic circuit 134 outputs a discharge control signal Dr3; the first input terminal of OR gate logic circuit 133 is coupled to the output terminal of AND gate logic circuit 132 to receive driving signal Vgs2, and the second input terminal of OR gate logic circuit 133 is coupled to the output terminal of NOT gate logic circuit 134 to receive discharge control signal Dr3; the output terminal of OR gate logic circuit 133 is coupled to the gate of switch Q3 to supply the gate of switch transistor Q3 with driving signal Vgs3. Wherein, switch transistor Q3 is an NMOS field-effect transistor. Of course, in other implementations, other types of transistors can be chosen as switch transistor Q4, as long as adjusting its control terminal signal as required to meet the following working principles.

Optionally, in some embodiments, the overcurrent protection signal OCP output by comparator 131 can be transmitted to the control signal generation module 110 to trigger the control signal generation module 110 to output invalid control signals Dr1 and Dr2 when the overcurrent protection signal OCP is valid; in some other embodiments, the overcurrent protection signal OCP output by the comparator 131 can be transmitted to driver 120 to trigger driver 120 to output the invalid driving signal Vgs1 when the overcurrent protection signal OCP is valid; in other embodiments, the overcurrent protection signal OCP output by comparator 131 can also be transmitted to control signal generation module 110 and driver 120 simultaneously.

When the overcurrent protection signal OCP output by comparator 131 is valid, it will trigger the converter to enter the protection state, i.e., the overcurrent protection state. In this embodiment, the effective state of the overcurrent protection signal OCP is a low-level state, and the ineffective state is a high-level state. However, other implementations are also possible; for example, the effective state of the overcurrent protection signal OCP is a high-level state, while the ineffective state is a low-level state.

In the example shown in FIG. 4, resistor R1 is an energy consumption element, and it consumes the residual charge on resonant capacitor Cr when the switch transistor Q3 is turned on, thereby achieving the purpose of releasing the residual voltage on the resonant capacitor Cr. However, the present application does not strictly restrict the types of energy consuming components. In other implementations, other components without inductors and capacitors can also be used as energy consuming components, such as transistors operating in an amplification region.

It can be understood that using resistor R1 as the energy consuming element may restrict the discharge current in the discharge circuit when discharging the resonant capacitor Cr.

The following will describe the working principles of driver 130 shown in FIG. 4.

When the flyback switch converter performs power output, driver 130 operates in the overcurrent detection mode, and at this point the enabling signal EN is in a valid state (such as high level), and the NOT gate logic circuit 134 outputs a low-level discharge control signal Dr3, such that the level state of drive signal Vgs3 is the same as that of drive signal Vgs2 (assuming the delay effect of the logic circuit is ignored), that is, the switch transistor Q3 is controlled by the drive signal Vgs2 to operate in turn-on or turn-off state; the overcurrent protection signal OCP is in an invalid state (such as high level), such that the level state of the driving signal Vgs2 is the same as the level state of the control signal Dr2; the control signal Dr2 provided by the control signal generation module 110 is a PWM signal with a certain duty cycle.

When the control signal Dr2 is in the high level state, both driving signal Vgs2 and driving signal Vgs3 are in the high level state, and switch transistors Q2 and Q3 are turned on. At this time, driver 130 samples the node voltage V_{SW} to obtain the voltage drop across the switch transistor Q2 to perform overcurrent detection; that is, the negative phase input terminal of comparator 131 receives a sampling signal and compares it with the overcurrent protection threshold Vref_ocp. When the sampling signal is less than the overcurrent protection threshold Vref_ocp, comparator 131 outputs an invalid (e.g., high level) overcurrent protection signal OCP, and the flyback switch converter maintains the power output state; when the sampling signal is greater than the overcurrent protection threshold Vref_ocp, comparator 131 outputs an effective (e.g., low level) overcurrent protection signal OCP, and the flyback switch converter enters the overcurrent protection state.

It can be understood that when switch transistors Q2 and Q3 are turned on, resistor R1 is equivalent to being short circuited, and thus resistor R1 coupled between the negative input end of comparator 131 and the reference ground will not have great influence on the voltage drop sampling result on transistor Q2, or the generated influence may be omitted, or the influence may be offset by regulating the overcurrent protection threshold Vref_ocp.

When the flyback converter is shut down or enters a protection state (including but not limited to entering the overcurrent protection state), driver 130 operates in the discharge mode, and at this time, control signal Dr2 is in an invalid state (e.g., low level) or the overcurrent protection signal OCP is in an effective state (e.g., low level), causing the drive signal Vgs2 to operate in a low level state, and witch transistor Q2 is turned off, and the switch transistor Q3 are controlled by the enabling signal EN to be turned on and off.

The enabling signal EN is in an invalid state (e.g., low level) in the discharge mode, and the NOT gate logic circuit 134 continuously outputs a valid (e.g., high level) discharge control signal Dr3, to make the switch transistor Q3 to continuously turn on under the control of the enabling signal EN in the discharge mode, thereby connecting the electrical connection path between resonant capacitor Cr and resistor R1, causing the residual voltage on resonant capacitor Cr to be released through resistor R1.

It should be noted that in the example shown in FIG. 4, the NOT gate logic circuit 134 actually exists as a discharge control unit, which is used to control the conducting time of the switch transistor Q3 when driver 130 operates in the discharge mode, thereby controlling the discharge time of the resonant capacitor Cr. Based on the working principle of the NOT gate logic circuit 134, it can be seen that in the example shown in FIG. 4, the discharge control unit is configured to continuously output an effective discharge control signal Dr3 when the received enabling signal EN is in the invalid state, in order to control the switch transistor Q3 to continue conducting when the enabling signal EN is in the invalid state.

Unlike the example shown in FIG. 4, in the example shown in FIG. 5, the NOT gate logic circuit 134 is replaced by timer 135; that is, in the example shown in FIG. 5, the discharge control unit includes a timer 135, which receives the enabling signal EN and starts timing when the enabling signal EN becomes invalid (e.g., low level), and stops timing when the timing value reaches the timing threshold Tn1, wherein the timing threshold Tn1 represents the first time, and the timer is configured to output a valid (e.g., high level) discharge control signal Dr3 during the timing period, so that the discharge control unit can only output a valid discharge control signal within the first time after the received enabling signal EN becomes invalid, so as to control the conducting time of switch transistor Q3, i.e., the control of the discharge time of resonant capacitor Cr.

In the example shown in FIG. 5, the timing threshold Tn1 is a pre-set value, which can be determined based on multiple times of experimental results, calculation results, or experiences.

The following explains the working process of driver 130 shown in FIG. 5.

When the flyback switch converter makes power output, driver 130 operates in the overcurrent detection mode. At this time, the enabling signal EN is in a valid state (e.g., high level), and timer 135 does not work and outputs a low-level discharge control signal Dr3, so that the level state of the drive signal Vgs3 is the same as that of the drive signal Vgs2 (assuming the delay effect of the logic circuit is ignored), that is, the switch transistor Q3 is controlled by the drive signal Vgs2 to operate in turn-on or turn-off state; the overcurrent protection signal OCP is in an invalid state (e.g., high level), so that the level state of the driving signal Vgs2 is the same as the level state of the control signal Dr2; the control signal Dr2 provided by the control signal generation module 110 is a PWM signal with a certain duty cycle.

When the control signal Dr2 is in the high level state, both driving signal Vgs2 and driving signal Vgs3 are in a high level state. Switch transistors Q2 and Q3 are turned on. At this time, driver 130 samples the node voltage V_{SW} to obtain the voltage drop across the switch transistor Q2 to perform overcurrent detection; that is, the negative phase input terminal of comparator 131 receives a sampling signal and compares it with the overcurrent protection threshold Vref_ocp. When the sampling signal is smaller than the overcurrent protection threshold Vref_ocp, comparator 131 outputs an invalid (e.g., high level) overcurrent protection signal OCP, and the flyback switch converter maintains the power output state; when the sampling signal is greater than the overcurrent protection threshold Vref_ocp, comparator 131 outputs an effective (e.g., low level) overcurrent protection signal OCP, and the flyback switch converter enters the overcurrent protection state.

When the flyback switch converter is turned off or enters the protection state (including but not limited to entering the overcurrent protection state), driver 130 operates in the discharge mode. At this time, the control signal Dr2 is in an invalid state (e.g., low level) or the overcurrent protection signal OCP is in an effective state (e.g., low level), so that drive signal Vgs2 is in the low state, the switch transistor Q2 is turned off, and the turning-on and off of the switch transistor Q3 are controlled by the enabling signal EN.

In the discharge mode, when the enabling signal EN becomes invalid (e.g., low level), timer 135 starts timing and outputs a valid (e.g., high level) discharge control signal Dr3, causing switch Q3 to conduct, thereby connecting the electrical connection path between resonant capacitor Cr and resistor R1, and releasing the residual voltage on resonant capacitor Cr through resistor R1; when the timing value of timer 135 reaches the timing threshold Tn1, timer 135 stops timing and outputs an invalid (e.g., low level) discharge control signal Dr3, which controls the switch transistor Q3 to turn off and the discharging ends.

In this example, by setting an appropriate timing threshold Tn1, the residual voltage on the resonant capacitor Cr can be released to the desired level before timer 135 stops timing, thereby reducing the energy loss of the flyback switch converter when it is shut down or enters the protection state.

Unlike the example shown in FIG. 5, in the example shown in FIG. 6, the timing threshold Tn1 is determined in response to the detection result of the voltage Ver across the two ends of the resonant capacitor Cr. That is, in the example shown in FIG. 6, the discharge control unit further comprises a voltage detection unit 136, which is used to detect the voltage Ver across the two ends of the resonant capacitor Cr in the discharge mode, and generate a triggering signal when the voltage Ver across the two ends of the resonant capacitor drops to a preset voltage threshold value, thereby determining the timing threshold Tn1 and triggering timer 135 to stop timing.

The following will explain the working process of driver 130 shown in FIG. 6.

When the flyback switch converter performs power output, driver 130 operates in the overcurrent detection mode, at this time the enabling signal EN is in a valid state (e.g., high level), timer 135 and voltage detection unit 136 do not work, and timer 135 outputs a low level discharge control signal Dr3 to make the level state of the drive signal Vgs3 be the same as that of the drive signal Vgs2 (assuming the delay effect of the logic circuit is ignored), that is, the switch transistor Q3 is controlled by the drive signal Vgs2 and is in turn-on or turn-off state; the overcurrent protection signal OCP is in an invalid state (e.g., high level), such that the level state of the driving signal Vgs2 is the same as the level state of the control signal Dr2; the control signal Dr2 provided by the control signal generation module 110 is a PWM signal with a certain duty cycle;

When the control signal Dr2 is in the high level state, both driving signals Vgs2 and Vgs3 are in the high level state, and switch transistors Q2 and Q3 are turned on. At this time, driver 130 samples the node voltage V_{SW} to obtain the voltage drop across switch transistor Q2 to perform the overcurrent detection; that is, the negative phase input terminal of comparator 131 receives a sampling signal and compares it with the overcurrent protection threshold Vref_ocp; wherein when the sampling signal is smaller than the overcurrent protection threshold Vref_ocp, comparator 131 outputs an invalid (e.g., high level) overcurrent protection signal OCP, and the flyback switch converter maintains the power output state; when the sampled signal is greater than the overcurrent protection threshold Vref_ocp, the comparator 131 outputs an effective (e.g., low level) overcurrent protection signal OCP, and the flyback switch converter enters the overcurrent protection state.

When the flyback converter is turned off or enters the protection state (including but not limited to entering the overcurrent protection state), driver 130 operates in the discharge mode. At this time, control signal Dr2 is in the invalid state (e.g., low level) or the overcurrent protection signal OCP is in the effective state (e.g., low level), so that drive signal Vgs2 is in the low state, and switch transistor Q2 is turned off, and the turning-on and off of switch transistor Q3 are controlled by the enabling signal EN.

In the discharge mode, when the enabling signal EN becomes invalid (e.g., low level), timer 135 starts timing, and voltage detection unit 136 begins to detect the voltage Ver across the two ends of resonant capacitor Cr. Timer 135 outputs a valid (e.g., high level) discharge control signal Dr3 before voltage detection unit 136 detects that voltage Ver at both ends of resonant capacitor Cr drops to the preset voltage threshold (i.e. before the voltage detection unit 136 outputs a valid trigger signal), causing the switch transistor Q3 to turn on, thereby connecting the electrical connection path between resonant capacitor Cr and resistor R1, to release the residual voltage on resonant capacitor Cr through resistor R1; timer 135 stops timing when voltage detection unit 136 detects that voltage Ver at both ends of the resonant capacitor drops to the preset voltage threshold (i.e. when the voltage detection unit 136 outputs a valid trigger signal), and outputs an invalid (e.g., low level) discharge control signal Dr3 to control the switch transistor Q3 to turn off and the discharging ends.

In this example, by detecting the voltage Ver at both ends of the resonant capacitor by voltage detection unit 136, the accurate timing threshold Tn1 can be determined according to different scenarios, which further reduces the energy loss of the flyback switch converter when it is shut down or enters the protection state while ensuring that the residual voltage on the resonant capacitor Cr can be released to the desired degree.

Unlike the example shown in FIG. 4, in the example shown in FIG. 7, driver 130 further comprises a switch transistor Q4. Switch transistor Q4 is connected in series between resistor R1 and the reference ground (of course, the setting positions of switch transistor Q4 and resistor R1 can be interchanged), and the control end of switch transistor Q4 receives a discharge control signal Dr3. Wherein, switch transistor Q4 is an NMOS field-effect transistor. Of course, in other implementations, other types of transistors can be chosen as switch transistor Q4, as long as regulating its control terminal signal as needed to meet the following working principles.

The following explains the working process of driver 130 shown in FIG. 7.

When the flyback switch converter performs the power outputs, driver 130 operates in the overcurrent detection mode, and at this time the enabling signal EN is in an effective state (e.g., high level), the NOT gate logic circuit 134 outputs a low-level discharge control signal Dr3, and switch transistor Q4 is in turn-off state. At the same time, the level state of driving signal Vgs3 is made to be same as that of driving signal Vgs2 (assuming the delay effect of the logic circuit is ignored), that is, the switch transistor Q3 is controlled by the driving signal Vgs2 to operate in turn-on or turn-off state; the overcurrent protection signal OCP is in an invalid state (e.g., high level), so that the level state of the driving signal Vgs2 is the same as the level state of the control signal Dr2; the control signal Dr2 provided by the control signal generation module 110 is a PWM signal with a certain duty cycle.

When the control signal Dr2 is in the high level state, both the driving signals Vgs2 and Vgs3 are in the high level state, and switch transistors Q2 and Q3 are turned on. At this time, driver 130 samples the node voltage V_{SW} to obtain the voltage drop across the switch transistor Q2 to perform overcurrent detection; that is, the negative phase input terminal of comparator 131 receives a sampling signal and compares it with the overcurrent protection threshold Vref_ocp; when the sampling signal is smaller than the overcurrent protection threshold Vref_ocp, comparator 131 outputs an invalid (e.g., high-level) overcurrent protection signal OCP, and the flyback switch converter maintains the power output state; when the sampling signal is greater than the overcurrent protection threshold Vref_ocp, the comparator 131 outputs an effective (e.g., low-level) overcurrent protection signal OCP, and the flyback switch converter enters the overcurrent protection state.

When the flyback switch converter is shut down or enters the protection state (including but not limited to entering the overcurrent protection state), driver 130 operates in the discharge mode; at this time, the control signal Dr2 is in an invalid state (e.g., low level) or the overcurrent protection signal OCP is in an effective state (e.g., low level), so that the drive signal Vgs2 is in a low state, the switch transistor Q2 is turned off, and the turning-on and off of switch transistors Q3 and Q4 are controlled by the enabling signal EN;

The enabling signal EN is in the invalid state (e.g., low level) in the discharge mode, and the NOT gate logic circuit 134 continuously outputs a valid (e.g., high level) discharge control signal Dr3, causing the switch transistors Q3 and Q4 to continue to turn on under the control of the enabling signal EN in the discharge mode, thereby connecting the electrical connection path between the resonant capacitor Cr and the resistor R1, allowing the residual voltage on the resonant capacitor Cr to be released through resistor R1.

It can be understood that in order to avoid or reduce the impact of resistance R1 on sampling accuracy, in the examples shown in FIGS. 4, 5, and 6, the conduction impedance of switch transistor Q3 needs to be much smaller than resistance R1. While in the example shown in FIG. 7, since the switch transistor Q4 is in turn-off state when the driver 130 samples the node voltage V_{SW}, it can well avoid the influence of resistance R1 on the sampling accuracy, thus allowing switch transistor Q3 to be selected as a switch transistor with larger conduction impedance, that is, a switch transistor with a smaller area can be selected as switch transistor Q3; meanwhile, in this example, the switch transistor Q4 is a low-voltage switch transistor with a smaller area, which can reduce the area of driver 130 and facilitate miniaturization. It can be understood that in some other implementations at this time, resistor R1 can also be removed, so that the residual voltage on the resonant capacitor Cr can be released by the conduction impedance of switch transistors Q3 and/or Q4 when they are turned on.

It should be noted that in the example shown in FIG. 7, the NOT gate logic circuit 134 actually exists as a discharge control unit, which is used to control the conducting time of switch transistors Q3 and Q4 when driver 130 operates in the discharge mode, thereby controlling the discharge time of the resonant capacitor Cr. Wherein, based on the working principle of the NOT gate logic circuit 134, it can be known that in the example shown in FIG. 4, the discharge control unit is configured to continuously output an effective discharge control signal Dr3 when the received enabling signal EN is in an invalid state, to control the continuous conduction of switch transistors Q3 and Q4 when the enabling signal EN is in an invalid state. In other examples of the present application, the NOT gate logic circuit 134 in FIG. 7 can also be replaced by the timer similar to the example shown in FIG. 5 or FIG. 6, thereby realizing the conduction time of switch transistors Q4 and Q5, i.e., the controlling the discharge time of resonant capacitor Cr. For example, in the discharge mode, when the enabling signal EN becomes invalid, the switch transistors Q3 and Q4 are controlled to turn on the first time based on the set timing threshold. Please refer to the description of FIG. 5 and FIG. 6 mentioned above for further understanding, and details omitted here.

It should be noted that in other embodiments of the present application, other types of protection circuits are also provided in the flyback switch converter, e.g., overvoltage protection, undervoltage protection, and over-temperature protection, etc. In these embodiments, the generation of the driving signal Vgs2 is also controlled by the protection signals output by each other type of protection circuit, and when any protection signal is effective, it will trigger the flyback switch converter to enter the protection state.

In summary, it can be understood that driver 130 illustrated in the examples of the present application, the switch transistor Q3 and comparator 131 constitute the overcurrent protection module of the flyback switch converter. The switch transistor Q3 and the energy consuming element (e.g., resistor R1), together with the inductor Lk and the primary edge winding Np of the transformer, form the discharge path for the resonant capacitor Cr. That is to say, in the embodiment of the present application, it is equivalent to multiplexing part of the circuit of its overcurrent protection module in driver 130 to realize the discharge of the resonant capacitor Cr. Based on this, simply modifying the control logic of the switch transistor Q3 can make driver 130 have both of the overcurrent detection function and the resonant capacitor discharge function, which realizes the release of residual voltage on the resonant capacitor Cr conveniently and almost without increasing cost, while the system complexity is very low.

Finally, it should be noted that the above embodiments are merely illustrative in this application, rather than limiting the implementation methods. For those of ordinary skill in the art, different forms of changes or variations can be made based on the above explanation. It is not necessary and impossible to exhaustively list all implementation methods here. The obvious changes or variations arising therefrom are still within the protection scope of this application.

What is claimed is:

1. A control circuit of a flyback switch converter, wherein the flyback switch converter comprises: a transformer, a first switch transistor, and a resonant capacitor in a resonant circuit formed when the first switch transistor is in turn-on state, and the control circuit is coupled to the first switch transistor, wherein the control circuit comprises:
a control signal generation module, for providing a first control signal;
a driver, coupled to the control signal generation module and the first switch transistor, configured to supply the first switch transistor with a first driving signal according to the first control signal, so as to control the first switch transistor to be turned on and off,
wherein the driver is for performing overcurrent detection according to a voltage drop across the first switch transistor when the flyback switch converter performs power output, and supplying the resonant capacitor with a discharge path when the flyback switch converter is shut down or enters a protection state.

2. The control circuit of claim 1, wherein the driver receives an enabling signal, and works in an overcurrent detection mode when the enabling signal is valid and works in a discharge mode when the enabling signal is invalid,
wherein the enabling signal is invalid when the flyback switch converter is shut down or enters the protection state, otherwise the enabling signal is valid;
in the overcurrent detection mode, the driver performs the overcurrent detection when the first driving signal is valid;
in the discharge mode, the driver supplies the resonant capacitor with the discharge path.

3. The control circuit of claim 2, wherein the driver comprises a second switch transistor;
in the overcurrent detection mode, the second switch transistor is controlled by the first driving signal to operate in turn-on or turn-off state, and the driver is configured to sample the voltage drop across the first switch transistor when the second switch transistor is in turn-on state to perform the overcurrent detection;
in the discharge mode, the second switch transistor is controlled by the enabling signal to turn on for at least a first time, and the driver is configured to supply the resonant capacitor with the discharge path when the second switch transistor is in turn-on state.

4. The control circuit of claim 2, wherein the driver comprises a second switch transistor and a third switch transistor;
in the overcurrent detection mode, the second switch transistor is controlled by the first driving signal to operate in turn-on or turn-off state, and the third switch transistor is controlled by the enabling signal to operate in turn-off state, the driver is configured to sample the voltage drop across the first switch transistor when the second switch transistor is in turn-on state to perform the overcurrent detection;
in the discharge mode, the second switch transistor and the third switch transistor are controlled by the enabling signal to turn on for at least a first time, and the driver is configured to supply the resonant capacitor with the discharge path when the second switch transistor and the third switch transistor are in turn-on state.

5. The control circuit of claim 3, wherein the discharge path comprises:
an energy consumption element, having a first terminal coupled to a reference ground, and a second terminal coupled to the resonant capacitor via the second switch transistor,
or an energy consumption element, having a first terminal coupled to the reference ground via the third switch transistor, and a second terminal coupled to the resonant capacitor via the second switch transistor.

6. The control circuit of claim 5, wherein the energy consumption element comprises a resistor element.

7. The control circuit of claim 3, wherein in the overcurrent detection mode, the second switch transistor is controlled by the first driving signal to turn on when the first switch transistor is turned on, so that the driver can sample the voltage drop across the first switch transistor when the first switch transistor is turned on to obtain a sampling signal,
wherein the driver outputs a valid overcurrent protection signal when the sampling signal is greater than a preset overcurrent protection threshold, and controls the flyback switch converter to operate in the overcurrent protection state.

8. The control circuit of claim 4, wherein in the overcurrent detection mode, the second switch transistor is controlled by the first driving signal to turn on when the first switch transistor is turned on, so that the driver can sample the voltage drop across the first switch transistor when the first switch transistor is turned on to obtain a sampling signal,
wherein the driver outputs a valid overcurrent protection signal when the sampling signal is greater than a preset overcurrent protection threshold, and controls the flyback switch converter to operate in the overcurrent protection state.

9. The control circuit of claim 3, wherein the driver further comprises:
a discharge control unit, having an input terminal which receives the enabling signal, and an output terminal which outputs a discharge control signal; wherein the discharge control unit is configured to control a conducting time of the second switch transistor in the discharge mode;
an OR gate logic circuit, having a first input terminal which receives the first driving signal, a second input terminal which receives the discharge control signal, and an output terminal coupled to a control end of the second switch transistor.

10. The control circuit of claim 9, wherein the discharge control unit is configured to continuously output the discharge control signal at valid state when the received enabling signal is in invalid state.

11. The control circuit of claim 9, wherein the discharge control unit is configured to output the discharge control signal at valid state within the first time after the received enabling signal is changed to invalid state.

12. The control circuit of claim 10, wherein the discharge control unit comprises:
a NOT gate logic circuit, having an input terminal which receives the enabling signal, and an output terminal which outputs the discharge control signal.

13. The control circuit of claim 11, wherein the discharge control unit comprises:
a timer, which receives the enabling signal and starts timing when the enabling signal is changed to invalid state, and stops timing when an obtained timing value reaches a timing threshold, which represents the first time,
wherein the timer is configured to output the discharge control signal at valid state during the timing.

14. The control circuit of claim 13, wherein the timing threshold is a preset value.

15. The control circuit of claim 13, wherein the timing threshold is determined in response to a detection result of a voltage across two ends of the resonant capacitor.

16. The control circuit of claim 15, wherein the discharge control unit further comprises:
a voltage detection unit for detecting the voltage across the two ends of the resonant capacitor in the discharge mode, and generating a triggering signal when the voltage across the two ends of the resonant capacitor drops to a preset voltage threshold, to trigger the timer to stop timing.

17. A flyback switch converter, comprising:
a transformer, a main switch transistor, a first switch transistor, and a resonant capacitor formed in the resonant circuit when the first switch transistor is in turn-on state;
the control circuit according to claim 1, coupled to the main switch transistor and the first switch transistor, respectively, to control the main switch transistor and the first switch transistor to be turned on and off, wherein the control circuit is further for performing overcurrent detection when the flyback switch transformer performs the power output according to the voltage drop across the first switch transistor, and supplying the resonant capacitor with the discharge path when the flyback switch converter is shut down or enters the protection state.

18. The flyback switch converter of claim 17, wherein the main switch transistor and the first switch transistor are sequentially connected in series between an input terminal of the flyback switch converter and a reference ground.

19. The flyback switch converter of claim 17, wherein the first switch transistor and the main switch transistor are sequentially connected in series between an input terminal of the flyback switch converter and a reference ground.

20. The flyback switch converter of claim 17, wherein the resonant capacitor, the first switch transistor, and the main switch transistor are sequentially connected in series between an input terminal of the flyback switch converter and a reference ground.
